(19) United States
(12) Patent Application Publication
(10) Pub. No.: US 2006/0250149 A1
(43) Pub. Date: Nov. 9, 2006

(54) Complex printed circuit board testing tool

(75) Inventor: Huang Mei Lan, Taipei County (TW)

Correspondence Address: BACON & THOMAS, PLLC, 625 SLATERS LANE, FOURTH FLOOR, ALEXANDRIA, VA, 22314, US

(73) Assignee: Unitech Printed Circuit Board Corp., TAIPEI (TW)

(21) Appl. No.: 11/120,988

(22) Filed: May 4, 2005

(51) Int. Cl. G01R 31/02

(52) U.S. Cl. 324/754

(57) ABSTRACT

The invention relates to a complex printed circuit board testing tool having a testing platform, a base disposed on the testing platform, a probe coupled to the testing platform and disposed on the base, and a conversion board disposed between the bases. The conversion board has a testing protrusion corresponding to the testing printed circuit board and a probe testing point corresponding to the probe. A pressure contact rubber covers the surface of the conversion board, so that the probe testing points on the printed circuit board contact with the protrusions on the conversion board through the pressure contact rubber, and the testing can be performed when the conversion board is in contact with the probe on the base, without using a probe of a special specification, and breaking through the limitation of testing areas and testing points. The invention saves costs and leaves no needle marks after the testing.

### BACKGROUND OF THE INVENTION

1. Field of the Invention

The present invention relates to a complex printed circuit board testing tool, and more particularly to an integration of a dedicated tool and a pressure contact rubber type tool (PCR tool) that uses a dedicated testing machine for a test, and the tool uses pressure contact rubbers and protrusions to substitute the probe used in traditional dedicated testing machines and tools, so as to prevent damages to the probe or producing probe points remained on a testing printed circuit board, break through the limited testing areas and testing points, and greatly reduce the cost of the tools.

2. Description of the Related Art

Traditionally, a printed circuit board (PCB) is tested by a testing procedure after its manufacture to see if the circuit of the printed circuit board is good. In general, the testing tools used by printed circuit board manufacturers is divided into a dedicated testing machine, a universal testing machine and a pressure contact rubber (PCR) testing machine. Referring to FIG. 1, the dedicated testing machine includes a retaining base and a tool disposed on the retaining base and having a probe. This kind of testing machine is cheap and features a fast testing speed, but the tool is expensive, particularly the elastic probe used for testing a precise circuit of a printed circuit board is very expensive and precise. It is necessary to replace the probe from time to time, since the probe is damaged easily, and thus causing an increase of testing cost.

On the other hand, the universal testing machine is expensive, but the probe of the universal testing machine is cheaper than that of a regular long-probe tool. After the testing printed circuit board passes the test and starts its mass production, a dedicated testing machine is used for testing the requirements for a mass production, but the dedicated testing machine still has the shortcomings of requiring expensive tools and frequently replacing the precise elastic probes.

In summation of the description above, using the traditional dedicated testing tools or PCR tools for testing printed circuit boards has the following drawbacks:

1. The dedicated tool incurs a higher cost. Although the dedicated tool can test a circuit board with a higher level of difficulty, the consumption and cost of the probes are much higher.

2. The PCR tool leaves no probe marks after the test, and such result cannot be accomplished by other types of tools. The PCR tool can test the printed circuit board with a level of difficulty even higher than the dedicated tool. However, the testing area and the testing points are limited and cannot be used in a large scale. Furthermore, the cost of this kind of testing machine is high.

In view of the foregoing drawbacks, manufacturers have made some improvements including the R.O.C. Patent Publication No. 367961 entitled “Conversion board for PCB dedicated testing machines and universal testing machines and tools” and R.O.C. Patent Publication No. 378756 entitled “Improved probe structure for complex tools”, these patents still have the following shortcomings:

The complex tool integrating the dedicated testing machine and the universal testing machine has a much lower cost than that of the dedicated testing tool, but the problem of having probe marks remained after the testing still exists. Such complex tool requires a complicated process to overcome the shortcomings for the manufacture.

### SUMMARY OF THE INVENTION

In view of the foregoing prior arts, the inventor of the present invention focused on the problems and started improving the prior art in hope of finding a feasible solution by conducting extensive researches and experiments and finally invented the complex printed circuit board testing tool in accordance with the present invention.

Therefore, it is a primary objective of the present invention to provide a complex printed circuit board testing tool, which comprises a base coupled with a testing machine and having a probe connected to a dedicated testing machine, and a conversion board disposed between the bases. The conversion board has a testing protrusion disposed thereon and corresponding to the testing printed circuit board, and a probe testing point corresponding to the probe. A pressure contact rubber is covered on the surface of the conversion board, so that the pressure contact rubber and the protrusion substitute the probe used for traditional dedicated testing machine and tools during a test, so as to prevent the probe from being damaged easily and any probe point remained on the testing printed circuit board. Such arrangement also breaks through the limitation of testing areas and testing points, and thus greatly reducing the cost of the tool.

To make it easier for our examiner to understand the technical measures taken to achieve the foregoing objective and its performance, we use a preferred embodiment together with the attached drawings for the detailed description of the invention.

### BRIEF DESCRIPTION OF THE DRAWINGS

FIG. 1 is a schematic view of a prior art device;

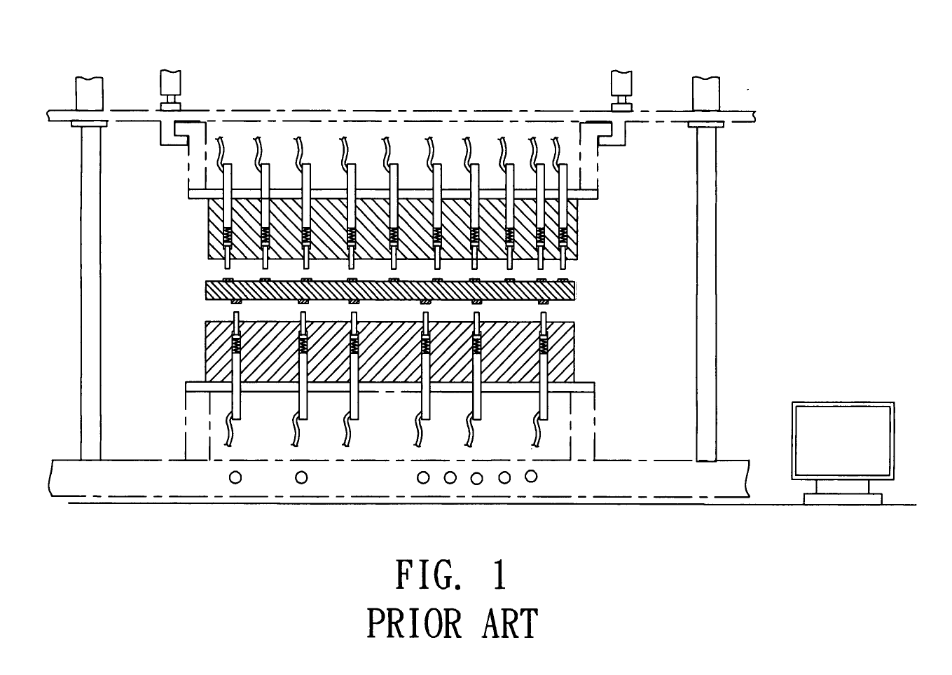

FIG. 2 is an exploded view of a tool of the present invention;

FIG. 3 is a cross-sectional view of a tool performing a test according to the present invention; and

FIG. 4 is a cross-sectional view of a printed circuit board placed on a testing machine according to the present invention.

### DETAILED DESCRIPTION OF THE PREFERRED EMBODIMENTS

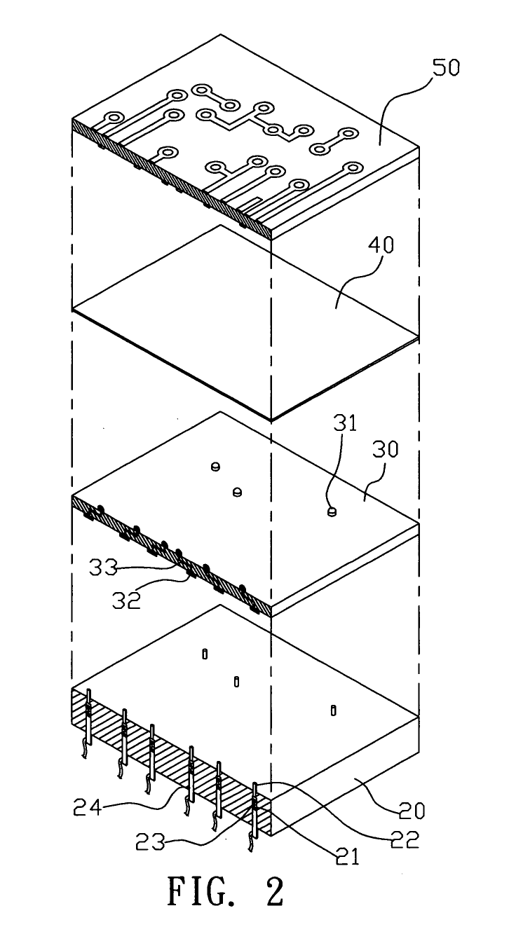

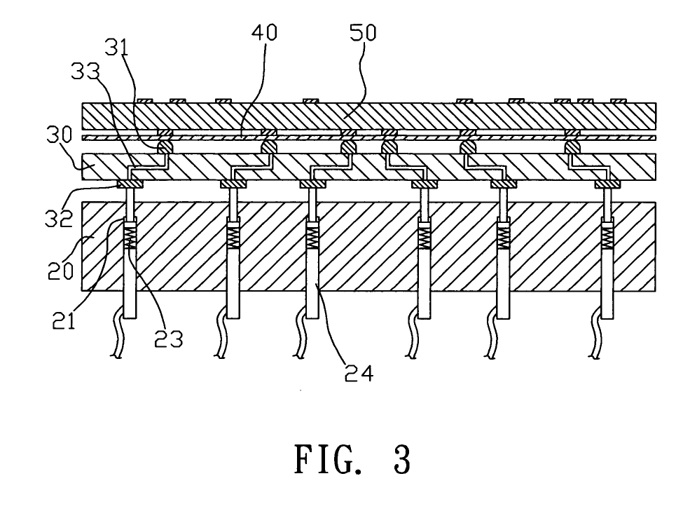

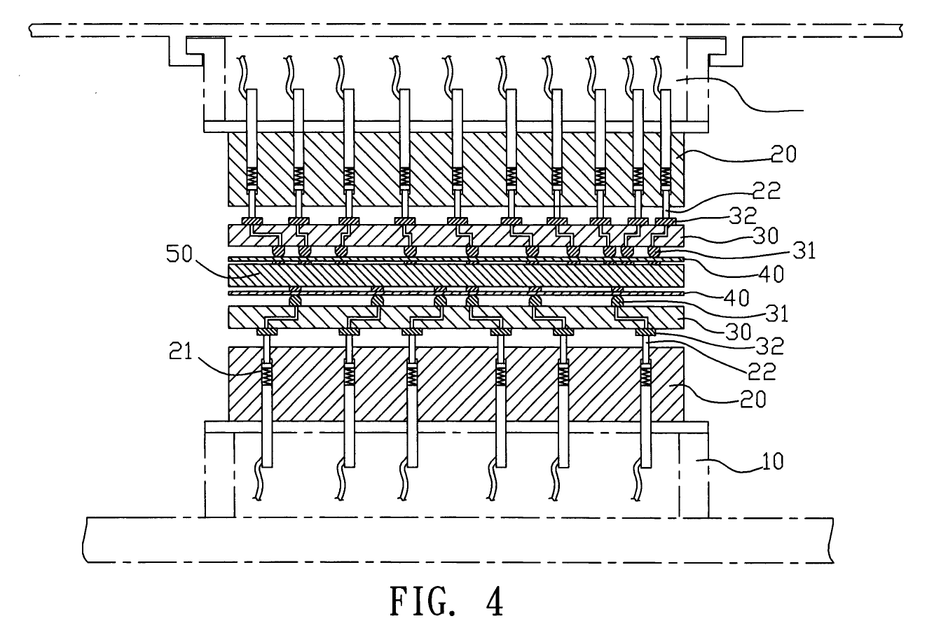

Referring to FIGS. 2 and 3 for the complex printed circuit board testing tool of the present invention, a tool for testing the open/short circuit of a testing printed circuit board is illustrated. The tool is installed on a testing machine as shown in the figures, and the testing machine is a dedicated testing machine. The testing machine has a platform 10 as shown in FIG. 4, and the platform has a relative base 20. FIG. 2 shows a lower base 20, and an upper base 20 has an identical structure as the lower base 20. The lower base 20 includes a plurality of insert holes 21, and the insert holes 21 vary according to the design of the testing printed circuit board. A probe 22 is inserted into the insert hole 21. One end of the probe 22 is protruded from the insert hole 21 and the other end is inserted deep inside the insert hole 21 and presses against a spring 23. Another end of the spring 23 presses against a conductive rod 24 and another end of the conductive rod is extended out of the insert hole 21 and connected to an electric signal circuit and connected to a dedicated testing machine through the circuit.

The base 20 has a conversion board 30, and one side of the conversion board 30 has a protrusion 31 corresponding to a testing point of a testing printed circuit board 50. The protrusion 31 is a copper pillar used in this embodiment, but those skilled in the art also can use other conductive materials for it. Another side of the conversion board 30 has a probe testing point 32 corresponding to the probe 22 of the base 20, and the probe testing point 32 is connected to the protrusion 21 through the electrically connected circuit 33. The electrically connected circuit 33 is a copper tinsel wire and is manufactured in the same way as the general printed circuit board. The conversion board 30 has a pressure contact rubber 40 covering a side of the conversion board 30 having the protrusion 31, and the pressure contact rubber 40 is electrically conductive along the vertically up and down direction but not along the left and right sideway direction. The pressure contact rubber 40 is disposed on a testing printed circuit board 50.

Referring to FIG. 4 for a testing, the upper and lower bases 20 are mounted onto the upper and lower ends of the platform 10, so that the upper and lower bases are kept with a specific distance. The conversion board 30 is placed on the upper and lower bases 20, and a pressure contact rubber 40 covers a surface of the conversion board 30, and then the testing printed circuit board 50 is clamped between the two pressure contact rubbers 40. If the upper and lower bases are pressed towards the middle, the protruded testing point of the testing printed circuit board 50 will press against the pressure contact rubber 40 and be in contact with the protrusion 31 corresponding to the pressure contact rubber 40. The remaining portion of the testing printed circuit board 50 will not be in contact with the conversion board 30, and thus the testing points in contact with the protrusion 31 can be in contact with the probe 22 through the probe testing point 32 and sends signals to the testing machine through the probe 22 for the testing.

In view of the above description, the invention has the following advantages:

1. Using a dedicated testing machine for the testing is cheap and fast.

2. For the printed circuit board used for mobile phones is very small in area, and the density of the probe testing points is high. It is necessary to have a very fine probe for the test to avoid short circuits. On the other hand, the present invention adopts a conversion board 30 of the adaptation, so that it is not necessary to directly contact the probe 22 with the testing printed circuit board 50. The probe 22 does not require a special specification, and thus greatly saving costs.

3. Since the protrusions 31 on the conversion board 30 can be made very tiny as needed, the testing areas and quantity of testing points per unit area can be increased.

4. Since the conversion board 30 is covered with a pressure contact rubber 40, it is not necessary to directly contact the testing printed circuit board 50 with the protrusions 31 on the conversion board 30, so as to prevent probed or pressed marks and further prevent the testing printed circuit board 50 from being damaged.

In summation of the above description, the complex printed circuit board testing tool of the present invention has a simple structure and fits the 4-wire micro-ohm (Ω) testing and can further save cost and improve performance, and thus the present invention complies with the patent application requirements and is submitted to the Patent and Trademark Office for review and granting of the commensurate patent rights.

What is claimed is:

1. A complex printed circuit board testing tool, comprising:
a base, coupled with a testing machine and having at least one probe, and said probe being installed at a specified position if needed;
a conversion board, disposed on said base and having a protrusion, and the position and quantity of said protrusions varies according to a printed circuit board, and a probe testing point being disposed on another side of said conversion board, and said probe testing point being coupled with its corresponding protrusion by an electrically connected circuit and corresponding to said probe; and
a pressure contact rubber, being covered onto a surface of said conversation board having said protrusions;
thereby, said probe testing points on said printed circuit board are in contact with said protrusion on said conversion board through said pressure contact rubber, and said conversion board is in contact with said probe on said base, for performing a test without using a probe of a special specification and breaking through the limitation of testing areas and testing points and leaving no probe mark on said testing printed circuit board.

2. The complex printed circuit board testing tool of claim 1, wherein said testing machine is a dedicated testing machine.

3. The complex printed circuit board testing tool of claim 1, wherein said protrusion is a copper pillar.

4. The complex printed circuit board testing tool of claim 1, wherein said electrically connected circuit is a copper tinsel wire.

5. The complex printed circuit board testing tool of claim 1, wherein said pressure contact rubber is electrically conductive in the vertically up and down direction, but not in the left and right sideway direction.
